(19) United States
(12) Patent Application Publication
(10) Pub. No.: US 2019/0013283 A1
(43) Pub. Date: Jan. 10, 2019

(54) Semiconductor package and manufacturing method thereof

(71) Applicant: POWERTECH TECHNOLOGY INC., HSINCHU COUNTY (TW)

(72) Inventors: HIROYUKI FUJISHIMA, HSINCHU COUNTY (TW); Shang-Yu Chang Chien, HSINCHU COUNTY (TW)

(21) Appl. No.: 15/646,055

(22) Filed: Jul. 10, 2017

(51) Int. Cl. H01L 23/00; H01L 21/56; H01L 23/31; H01L 25/065; H01L 21/683

(52) U.S. Cl. CPC H01L 24/03; H01L 2224/02311; H01L 21/563; H01L 23/3114; H01L 25/0657; H01L 21/6835; H01L 24/81; H01L 24/85; H01L 24/13; H01L 2224/02379; H01L 2224/13024; H01L 2224/81005; H01L 2224/85005; H01L 2225/0651; H01L 2225/06562; H01L 2224/04105; H01L 2224/03003; H01L 2221/68359; H01L 21/568

(57) ABSTRACT

A method of forming a Fan-Out Wafer Level semiconductor device includes forming only a plurality of metal bonding pads on a glass carrier. Electrode pads of a semiconductor chip are coupled to the plurality of metal bonding pads. The semiconductor chip and the plurality of metal bonding pads are encapsulated with a molding compound. The glass carrier can then be removed to expose a surface of the FOWLP structure. A redistribution layer is then formed on the exposed surface of the FOWLP structure. At least one metal trace within the redistribution layer is in electrical contact with the plurality of metal bonding pads. Solder balls may be mounted on the redistribution layer to provide electrical contact between the solder balls and the electrode pads of the semiconductor chip.

### BACKGROUND OF THE INVENTION

### 1. Field of the Invention

This disclosure relates to a Fan-Out Wafer Level Package (FOWLP) structure and more specifically to an FOWLP structure and fabricating method to improve connectivity between a semiconductor chip and bonding pads.

### 2. Description of the Prior Art

Referring to FIG. 1, conventionally, manufacture of an FOWLP structure 100 includes forming a redistribution layer (RDL) 110 on a glass carrier 120. Metal bonding pads 130 are then applied to the RDL 110. A semiconductor chip 140 is next attached to the metal bonding pads 130 and the FOWLP structure 100 completed in subsequent processing. This conventional manufacturing method often results in the metal bonding pads 130 having height and flatness variability that reduces connectivity between the semiconductor chip 140 and metal bonding pads 130 as seen in FIG. 1. When the metal bonding pads are not flat, it also is difficult to bump connect the chip.

The height variability of the bonding pads 130 can be due to warpage of the FOWLP structure 100 during processing and/or influence of patterning of the RDL 110 layers between the glass carrier 120 and the metal bonding pads 130, increasing as the layer count increases. Currently, an attempt to keep the metal bonding pads 130 flat requires the use of sheet Polyimide (PI) or a squeegee PI process, either of which increases costs and manufacturing complexity.

### SUMMARY OF THE INVENTION

A Fan-Out Wafer Level semiconductor device comprises a glass carrier having a plurality of metal bonding pads arranged on and adjacent to the glass carrier. A semiconductor chip has an active surface whereon a plurality of electrode pads are formed and has at least one of the plurality of electrode pads in electrical contact with a first surface of at least one of the plurality of metal bonding pads. An underfill may be present in spaces between the semiconductor chip and the glass carrier and a molding compound encapsulating the semiconductor chip, the underfill, and the plurality of metal bonding pads, wherein a surface of the molding compound is substantially co-planar with a second surface, opposite to the first surface, of the plurality of metal bonding pads. At least one component, other than the semiconductor chip, may be in electrical contact with at least one of the plurality of metal bonding pads.

Another Fan-Out Wafer Level semiconductor device comprises a plurality of metal bonding pads coplanar to each other and a semiconductor chip having an active surface whereon a plurality of electrode pads are formed, the plurality of electrode pads is correspondingly coupled to and electrically connected with the plurality of metal bonding. A molding compound encapsulates the semiconductor chip and the plurality of metal bonding pads and has a surface coplanar to a surface of each of the plurality of metal bonding pads. A redistribution layer is formed on the molding compound and is electrically connected to the plurality of metal bonding pads. The Fan-Out Wafer Level semiconductor device may further comprise a passivation layer formed to have a planar surface and planarly disposed on the molding compound and the plurality of metal bonding pads. The Fan-Out Wafer Level semiconductor device may further comprise a conductive layer formed to have a planar surface and be planarly disposed on the passivation layer and is electrically connected to the plurality of metal bonding pads through conductive circuits formed to be coplanar to the plurality of metal bonding pads and through vias of the passivation layer electrically coupled to the conductive circuits. The Fan-Out Wafer Level semiconductor device of may further comprise conductive circuits formed to be coplanar and electrically connected to the plurality of metal bonding pads and through vias of the passivation layer electrically connected to the conductive circuits, the through vias being formed on only the periphery of the metal bonding pads. The Fan-Out Wafer Level semiconductor device may further comprise at least one component in electrical contact with the plurality of metal bonding pads.

A method of forming a Fan-Out Wafer Level semiconductor device comprises providing a glass carrier, forming a plurality of metal bonding pads on the glass carrier and electrically connecting at least one of a plurality of electrode pads formed on an active surface of a semiconductor chip with at least one of the plurality of metal bonding pads. An underfill may be filled into spaces between the semiconductor chip and the glass carrier. A molding compound may encapsulate the semiconductor chip and the plurality of metal bonding pads. The glass carrier may be removed to expose a surface of the FOWLP structure. A redistribution layer can then be formed on the exposed surface of the FOWLP structure.

Another method of forming a Fan-Out Wafer Level semiconductor device, the method comprises providing a first glass carrier and forming a plurality of metal bonding pads on the first glass carrier. A plurality of electrode pads formed on an active surface of a semiconductor chip is electrically connected with the plurality of metal bonding pads on the first glass carrier. The first glass carrier may be covered with a molding compound encapsulating the semiconductor chip and the plurality of metal bonding pads, a surface of the molding compound most adjacent to the first glass carrier substantially co-planar with a surface of the plurality of metal bonding pads most adjacent to the first glass carrier. The first glass carrier is then removed and a redistribution layer is formed on the plurality of bonding pads and a non-active surface of the semiconductor chip with at least one metal trace within the redistribution layer in electrical contact with the at least one of the plurality of metal bonding pads. A non-active surface of the semiconductor chip is adjacent to the first glass carrier and the plurality of electrode pads may be electrically connected with the plurality of metal bonding pads using wire bonding. At least one component, other than the semiconductor chip, may be electrically connected with the plurality of metal bonding pads. A passivation layer may be formed to have a planar surface and planarly disposed on the molding compound and the plurality of metal bonding pads. A conductive layer may be formed to have a planar surface, planarly disposed on the passivation layer, and electrically connected to the plurality of metal bonding pads through conductive circuits formed to be coplanar to the plurality of metal bonding pads and through vias of the passivation layer electrically coupled to the conductive circuits. Solder balls may be mounted on the redistribution layer with at least one of the solder balls in electrical contact with the at least one metal trace.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a side-view cutaway drawing of a FOWLP of the prior art showing flatness variability of the metal bonding pads.

FIGS. 2-10 are side-view cutaway drawings of steps for fabrication of an FOWLP device according to embodiments of the disclosure.

FIGS. 11-17 are side-view cutaway drawings of steps for fabrication of an FOWLP device according to other embodiments of the disclosure.

FIG. 18 is a basic flow chart of the fabrication method of an FOWLP structure according to the disclosure.

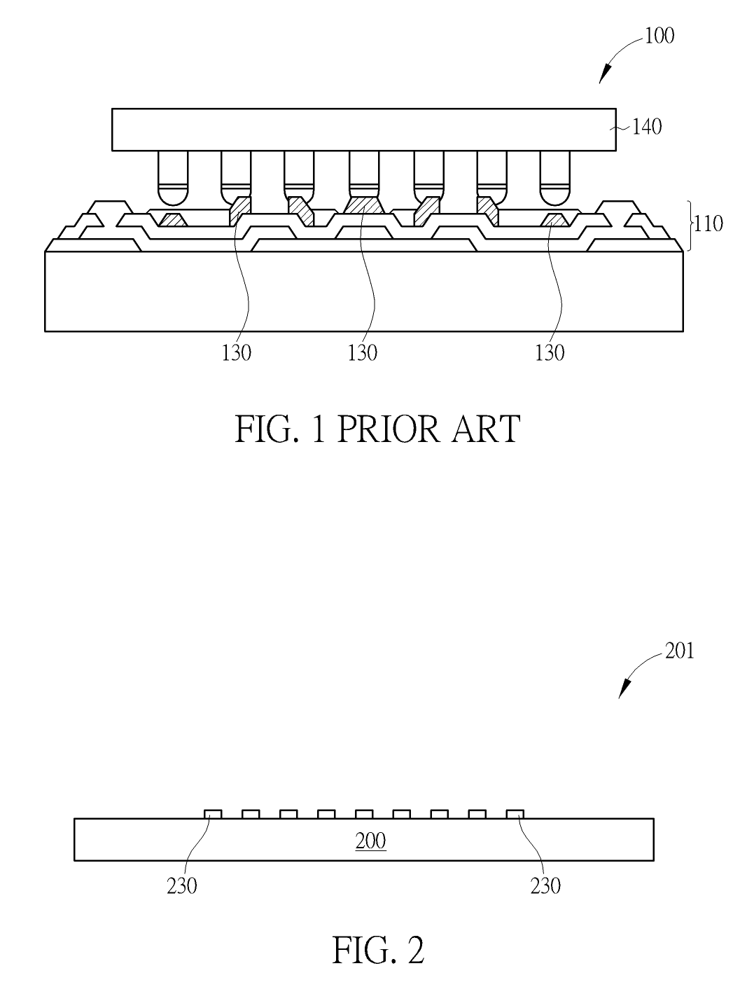

### DETAILED DESCRIPTION

To overcome the prior art problem of flatness variability of metal bonding pads leading to bumping and connectivity problems, a novel method of Fan-Out Wafer Level Package (FOWLP) fabrication is proposed.

As shown in FIG. 2, to fabricate the FOWLP structure 201, a first glass carrier 200 is provided. A plurality of metal bonding pads 230 are formed on the first glass carrier 200 according to at least one alignment mark (not shown). The metal bonding pads may be formed on the first glass carrier 200 using an electroplating process, such as depositing a layer of metal on the on the first glass carrier 200, masking the layer of metal, removing the undesired portions of the mask, etching the layer of metal to remove undesired portions and have the remaining of the layer of metal to form the metal bonding pads, and removing the mask remaining on the carrier 200. Some embodiments may form the metal bonding pads using an alternative method, such as depositing solder balls on the first glass carrier which are reflowed when the semiconductor chip is bonded to the metal bonding pads 130. Additionally, some embodiments may include an adhesive and/or an unpatterned UV passivation layer between the first glass carrier 200 and the metal bonding pads 130 to facilitate eventual removal of the first glass carrier 200.

Forming the bonding pads 230 firstly and substantially directly on the flat surface of the first glass carrier 200 greatly reduces prior art height and flatness variability of the metal bonding pads 230. Furthermore, warpage and/or influence of patterning of RDL layers between the glass carrier and the metal bonding pads are eliminated. The need for costly sheet Polyimide (PI) or a squeegee PI process is also removed while greatly decreasing difficulty in bump connecting the semiconductor chip.

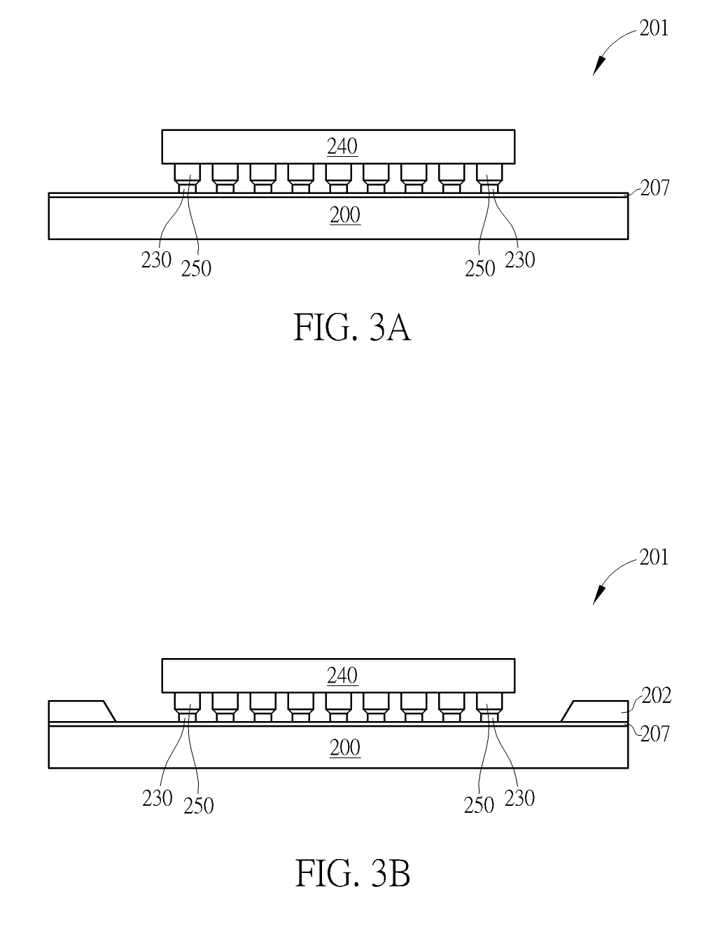

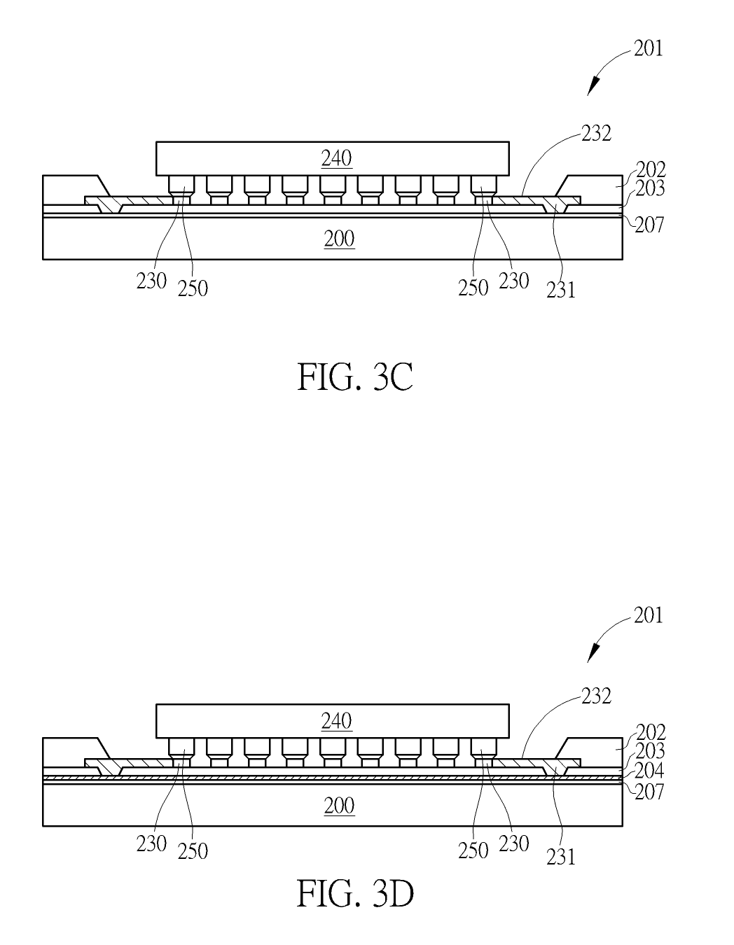

A semiconductor chip 240 may be an integrated circuit. The semiconductor chip 240 may have an active surface whereon a plurality of electrode pads 250 are formed and a non-active surface opposite the active surface. When flip-chip bonding is used, such as in embodiments shown in FIG. 2-FIG. 10, the plurality of electrode pads 250 is correspondingly coupled to and electrically connected with the plurality of metal bonding pads 230 as shown in FIGS. 3A-3D.

As stated, some embodiments may include an adhesive and/or an unpatterned UV passivation layer and/or other layers between the first glass carrier 200 and the metal bonding pads 130. For example, FIG. 3A has an adhesive layer 207 between the first glass carrier 200 and the metal bonding pads 130.

To avoid risk of adhesion between a later added molding compound and the adhesive layer 207, some embodiments place a Polyimide (PI) layer 202 on the adhesive layer 207 and the Polyimide (PI) layer 202 surrounds the metal bonding pads 230 as shown in FIG. 3B. Because the PI layer is surrounding the metal bonding pads 230, the metal bonding pads 230 are not deformed due because the metal bonding pads 230 are formed on the flat surface of the adhesive layer 207.

To avoid risk of adhesion between a molding compound/CUF (Capillary Underfill) and the adhesive layer 207, some embodiments place a second PI layer 203 between the adhesive layer 207 and the metal bonding pads 230 as shown in FIG. 3C. The metal bonding pads 230 are formed on the flat surface of the PI layer 203 and surrounded by the PI layer 202. Thus, the metal bonding pads 230 will not be deformed when formed on the carrier 200. Through vias 231 are formed in the PI layer (s) 203 to expose a surface of the through vias 231 after demounting for further formation of electrical connection. The through vias are not formed on areas of the PI layer (s) 203 where the metal bonding pads 130 are formed.

As shown in FIG. 3D, some embodiments may additionally form a conductive layer 204 between the adhesive layer 207 and the metal bonding pads 130. In some embodiments, the conductive layer 204 may be disposed between the second PI layer 203 and the adhesive layer 207. The conductive layer 204 is unpatterned before the formation of the metal bonding pads 230, but may be patterned after demounting of the first glass carrier 200. The conductive layer 204 can be electrically connected to the metal bonding pads 130 with through the through vias 231 formed in the PI layer(s) 203 and a conductive circuit 232 coupling the metal bonding pads to the through vias 231. The through vias are not formed on areas of the PI layer(s) 203 where the metal bonding pads 130 are formed.

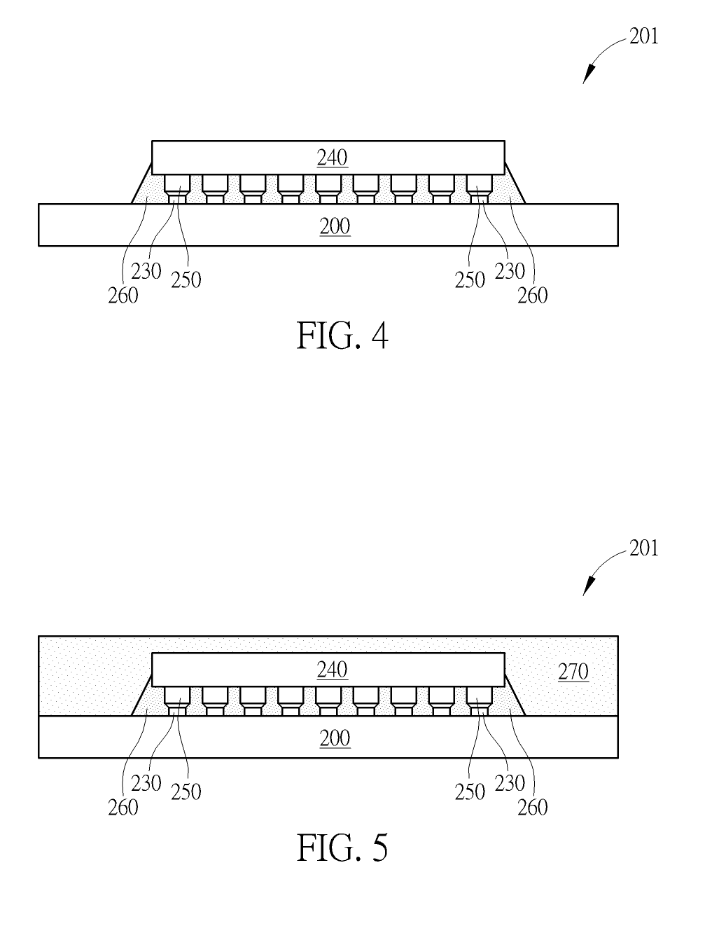

As shown in FIG. 4, an underfill 260 may then be filled into spaces between the semiconductor chip 240 and the first glass carrier 200. FIG. 5 shows a molding compound 270 formed on the structure to encapsulate the semiconductor chip 240, the underfill 260, and the plurality of metal bonding pads 230. The molding compound 270 may be an epoxy molding compound (EMC). Because of the formation of the metal bonding pads on the first glass carrier 200, a surface of the molding compound 270 most adjacent to the first glass carrier 200 is substantially co-planar with a surface of the plurality of metal bonding pads 230 most adjacent to the first glass carrier 200.

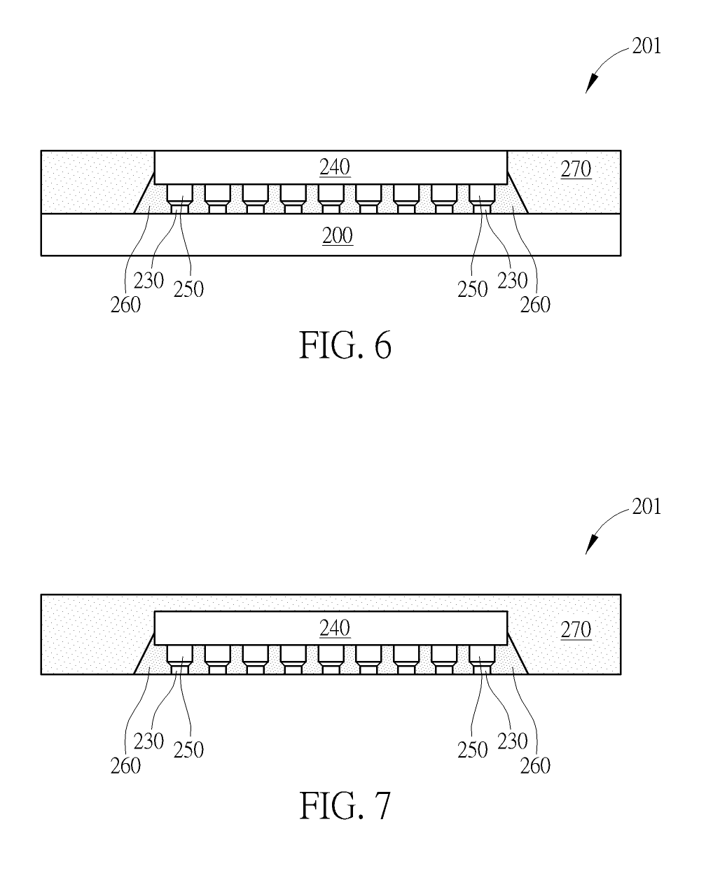

As shown in FIG. 6, in some embodiments, the molding compound 270 may then be ground so that a surface of the molding compound 270 least adjacent to the first glass carrier 200 is substantially co-planar with a non-active surface of the semiconductor chip 240.

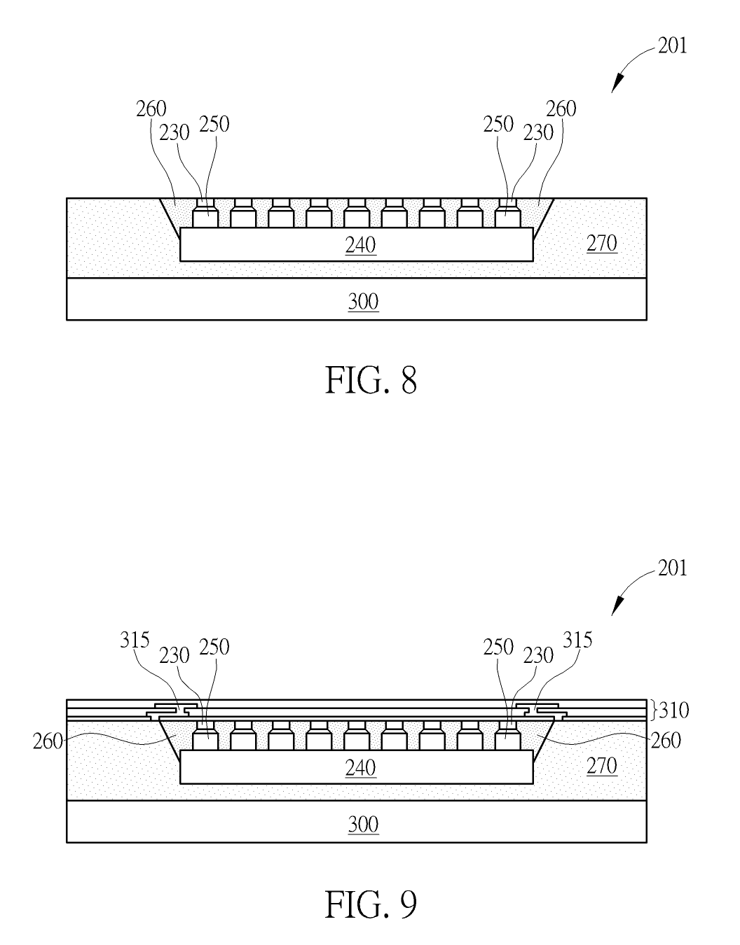

The first glass carrier 200 may then be removed to expose the plurality of metal bonding pads 230, the underfill 260, and a first surface of the molding compound 270 as shown in FIG. 7. FIG. 8 illustrates that a second glass carrier 300 may then be mounted to a second surface of the molding compound, the semiconductor chip being between the first surface of the molding compound and the second surface of the molding compound.

Referring to FIG. 9, a redistribution layer 310 may then be formed on the active surface of the semiconductor chip 240, the plurality of bonding pads 230, the underfill 260, and the first surface of the molding compound 270. At least one metal trace 315 within the redistribution layer 310 may be electrically connected with at least one of the plurality of metal bonding pads 230. The redistribution layer 310 may comprise one or more layers of dielectric and one or more layers of metal, patterned to provide desired electrical connections.

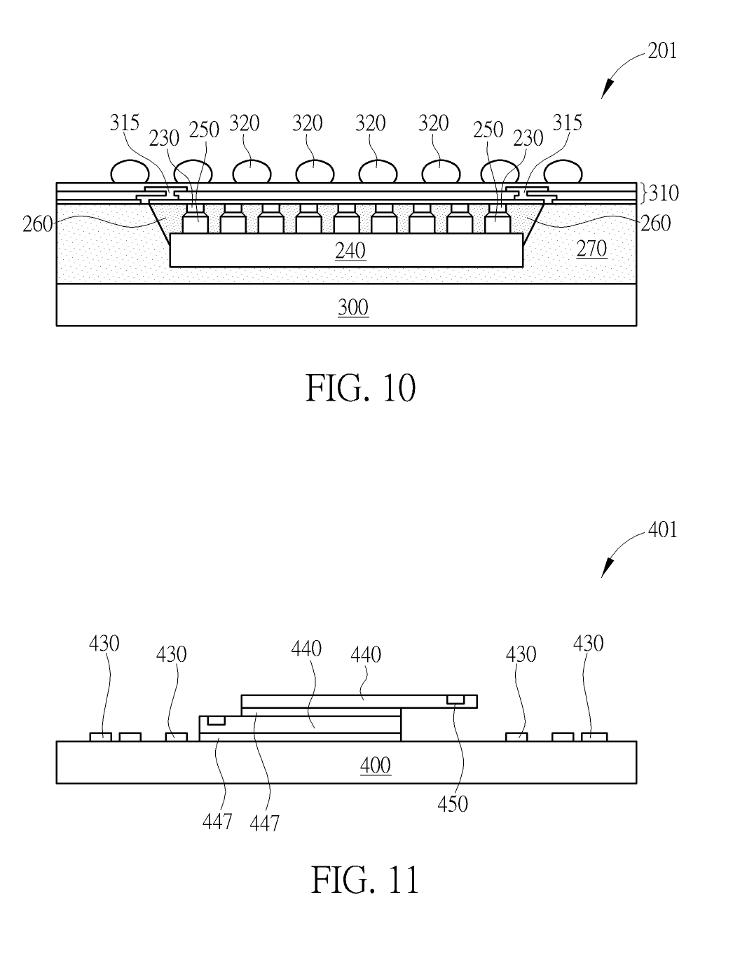

Solder balls 320 may then be mounted on the redistribution layer 315 using under-ball metallization or an appropriate process. At least one metal trace 315 within the redistribution layer 310 is electrically connected to the plurality of metal bonding pads 230 as shown in FIG. 10. When no further processing is desired, the second glass carrier 300 may be removed and a plurality of FOWLP structures 201 formed on a single carrier may be singulated.

When wire bonding is used, such as in embodiments shown in FIG. 11-FIG. 17, the FOWLP may be formed using similar process. In FIG. 11 a first glass carrier 400 is provided and metal bonding pads 430 are formed on the first glass carrier 400 in the same manner and with the same benefits as previously described.

FIG. 12 shows how the semiconductor chip 440 may be an integrated circuit. The semiconductor chip 440 may have an active surface whereon a plurality of electrode pads 450 are formed and a non-active surface opposite the active surface. The non-active surface of the semiconductor chip 440 may be applied to the first glass carrier 400. There may be an adhesive 447 between the semiconductor chip 440 and the first glass carrier 400. A plurality of electrode pads 450 formed on the active surface of the semiconductor chip 440 is correspondingly coupled to and electrically connected with the plurality of metal bonding pads 430.

As shown in FIGS. 11-17, the semiconductor chip 440 may be a stack of semiconductor chips 440. In this situation, an adhesive 447 may be placed between each of the semiconductor chips 440 and between the bottom semiconductor chip 440 and the first glass carrier 400. Each of the stacked semiconductor chips 440 may have an active surface whereon a plurality of electrode pads 450 are formed and a non-active surface opposite the active surface. The electrode pads 450 of each of the stacked semiconductor chips 440 may be correspondingly coupled to and electrically connected with the plurality of metal bonding pads 430.

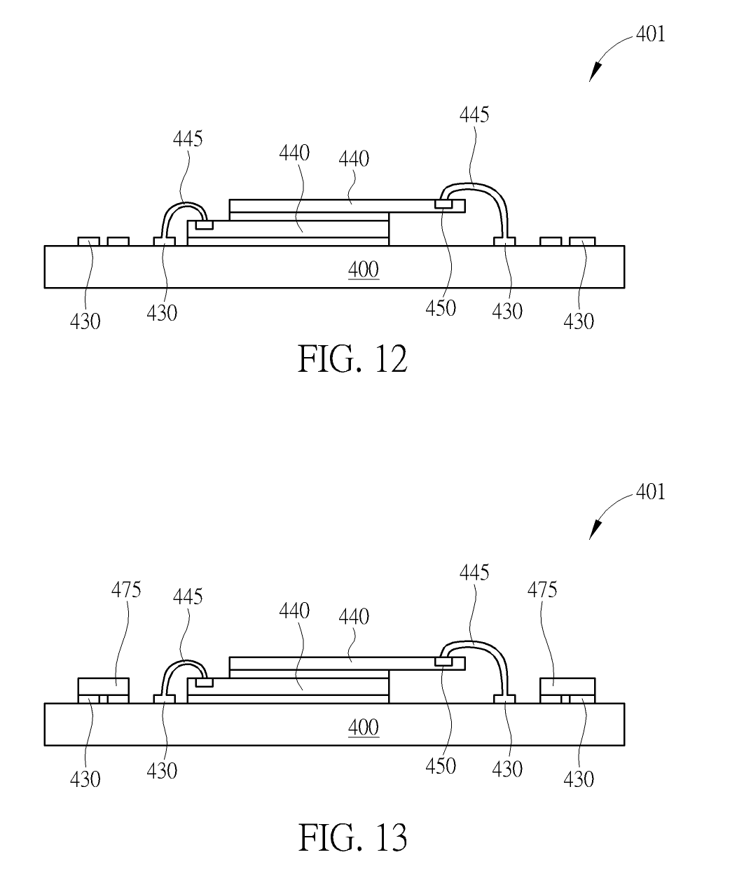

In some embodiments, an additional component 475 other than the semiconductor chip 440 may be desired within the package. Examples of such a component may include, inter alia, an amplifier, a diode, three-terminal devices such as a transistor, and/or four-terminal devices such as a sensor. When desired, one or more of these components 475 may be mounted on and in electrical contact with metal bonding pads 430 not used by the semiconductor chip 440 as shown in FIG. 13.

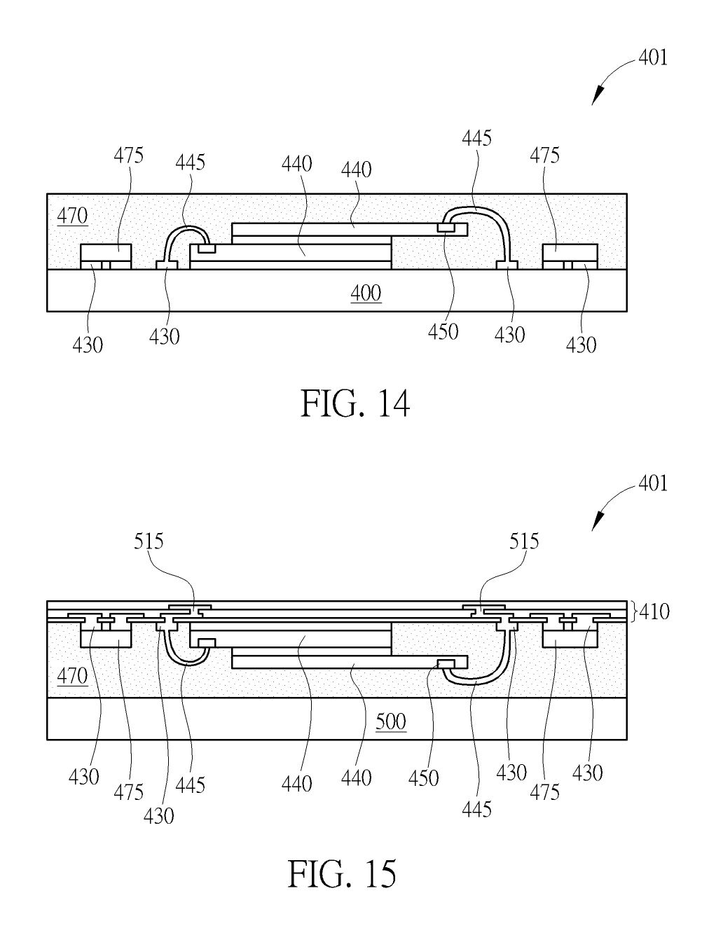

With or without the component 475, a molding compound 470 (preferably an EMC) is then formed that encapsulates the semiconductor chip 440, the wire bonding 445, the component (s) 475 when present, and the plurality of metal bonding pads 430 as shown in FIG. 14. The first glass carrier 400 may then be removed to expose a surface of the plurality of metal bonding pads 430, the non-active surface of the semiconductor chip 440, and a first surface of the molding compound 470. A second glass carrier 500 may then be mounted to a second surface of the molding compound 470, the semiconductor chip 440 being between the first surface of the molding compound 470 and the second surface of the molding compound 470 as shown in FIG. 15.

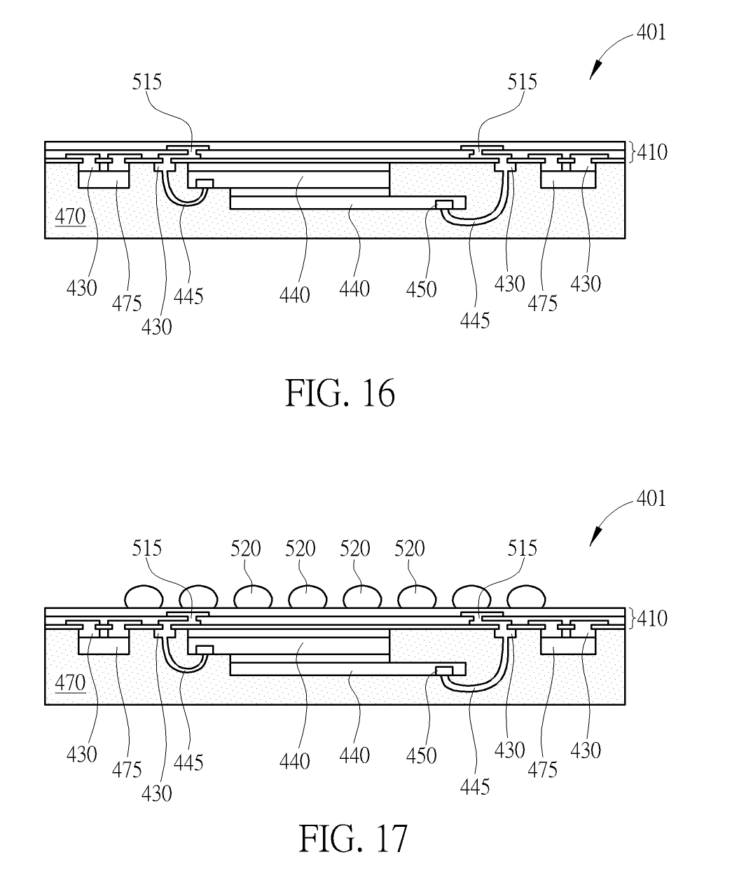

Referring to FIG. 16, next a redistribution layer 410 may then be formed on the exposed surface of the plurality of metal bonding pads 430, the non-active surface of the semiconductor chip 440, and the first surface of the molding compound. At least one metal trace 515 within the redistribution layer 410 may be in electrical contact with at least one of the plurality of metal bonding pads 430. The redistribution layer 410 may comprise one or more alternating layers of a dielectric and a metal, patterned to provide desired electrical connections.

Solder balls 520 may then be mounted on the redistribution layer 410 using an under-ball metallization process or another appropriate process. The at least one metal trace 515 within the redistribution layer 410 is in electrical contact with at least one of the solder balls 520 as shown in FIG. 17. When no further processing is desired, the second glass carrier 500 may be removed and a plurality of FOWLP structures 401 formed on a single carrier may be singulated.

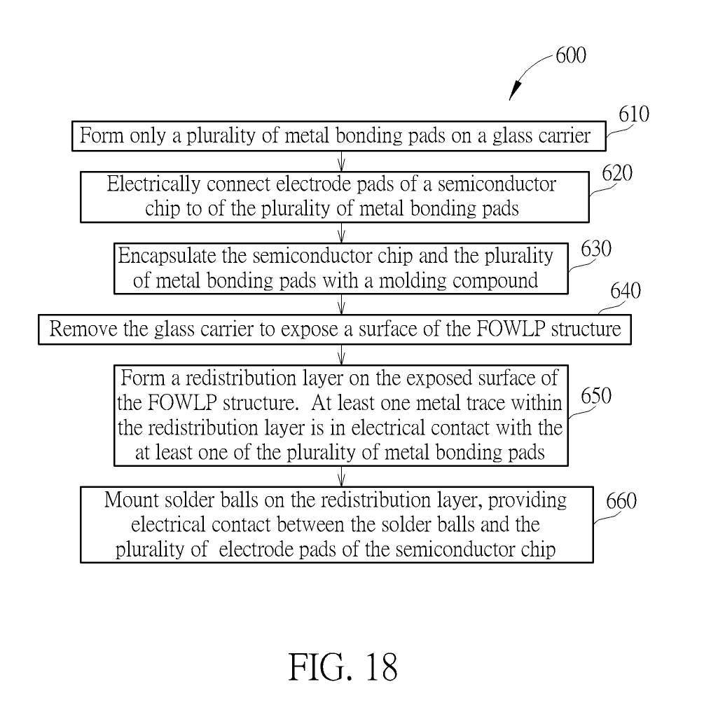

FIG. 18 is a non-limiting flow chart 600 of one fabrication method of an FOWLP structure according to the above disclosure. Implementation of the method may omit some of the recited steps and/or include additional steps as required and described above.

Step 610: Form only a plurality of metal bonding pads on a glass carrier.

Step 620: Electrically connect electrode pads of a semiconductor chip to the plurality of metal bonding pads.

Step 630: Encapsulate the semiconductor chip and the plurality of metal bonding pads with a molding compound.

Step 640: Remove the glass carrier to expose a surface of the FOWLP structure.

Step 650: Form a redistribution layer on the exposed surface of the FOWLP structure.

Step 660: Mount solder balls on the redistribution layer, providing electrical contact between the solder balls and the plurality of electrode pads of the semiconductor chip.

The novel method of FOWLP fabrication and associated device described above overcomes the prior art problem of flatness variability of metal bonding pads due to warpage and/or influence of patterning of RDL layers between the glass carrier and the metal bonding pads, eliminates the need for costly sheet Polyimide (PI) or a squeegee PI process, and facilitates bump connecting of the semiconductor chip.

Those skilled in the art will readily observe that numerous modifications and alterations of the device and method may be made while retaining the teachings of the invention. Accordingly, the above disclosure should be construed as limited only by the metes and bounds of the appended claims.

1: A Fan-Out Wafer Level semiconductor device comprising:
a plurality of metal bonding pads coplanar to each other;
a passivation layer surrounding the plurality of metal bonding pads;
a semiconductor chip having an active surface whereon a plurality of electrode pads are formed, the plurality of electrode pads is correspondingly coupled to and electrically connected with the plurality of metal bonding pads;
a molding compound encapsulating the semiconductor chip and the plurality of metal bonding pads, the molding compound having a surface coplanar to a surface of each of the plurality of metal bonding pads, the molding compound, the passivation layer, and the plurality of metal bonding pads all disposed on a same side of the surface coplanar to the surface of each of the plurality of metal bonding pads; and
a redistribution layer formed on the molding compound and electrically connected to the plurality of metal bonding pads.

2: The Fan-Out Wafer Level semiconductor device of claim 1 further comprising the metal bonding pads are formed on another passivation layer and surrounded by the passivation layer.

3: The Fan-Out Wafer Level semiconductor device of claim 2 further comprising a conductive layer formed to have a planar surface, planarly disposed on the another passivation layer, and electrically connected to the plurality of metal bonding pads through conductive circuits formed to be coplanar to the plurality of metal bonding pads and through vias of the another passivation layer electrically coupled to the conductive circuits.

4: The Fan-Out Wafer Level semiconductor device of claim 2 further comprising conductive circuits formed to be coplanar and electrically connected to the plurality of metal bonding pads; and
through vias of the another passivation layer, electrically connected to the conductive circuits, the through vias being formed on only the periphery of the metal bonding pads.

5: The Fan-Out Wafer Level semiconductor device of claim 1 further comprising an underfill in spaces between the semiconductor chip and the molding compound encapsulating the semiconductor chip, the underfill, and the plurality of metal bonding pads.

6: The Fan-Out Wafer Level semiconductor device of claim 1 wherein the plurality of electrode pads is in electrical contact with a first surface of the plurality of metal bonding pads using wire bonding, and the molding compound encapsulates the semiconductor chip, the wire bonding, and the plurality of metal bonding pads, a surface of the molding compound substantially co-planar with a second surface, opposite to the first surface, of the plurality of metal bonding pads.

7: The Fan-Out Wafer Level semiconductor device of claim 6 further comprising at least one component, other than the semiconductor chip, in electrical contact with the plurality of metal bonding pads, and the molding compound encapsulates the semiconductor chip, the wire bonding, the at least one component, and the plurality of metal bonding pads.

8: The Fan-Out Wafer Level semiconductor device of claim 1 wherein a surface of the molding compound least adjacent to the redistribution layer is substantially co-planar with a non-active surface of the semiconductor chip.

9: A method of forming a Fan-Out Wafer Level semiconductor device, the method comprising:
providing a first glass carrier;
forming a plurality of metal bonding pads on a side of the first glass carrier;
forming a passivation layer on the side of the first glass carrier, the passivation layer surrounding the plurality of metal bonding pads;
electrically connecting a plurality of electrode pads formed on an active surface of a semiconductor chip with the plurality of metal bonding pads on the side of the first glass carrier;
covering the side of the first glass carrier with a molding compound encapsulating the plurality of metal bonding pads;
removing the first glass carrier; and
forming a redistribution layer on the plurality of bonding pads and a non-active surface of the semiconductor chip, at least one metal trace within the redistribution layer in electrical contact with the at least one of the plurality of metal bonding pads.

10: The method of forming a Fan-Out Wafer Level semiconductor device of claim 9 further comprising covering the first glass carrier with the molding compound encapsulating the semiconductor chip and the plurality of metal bonding pads, a surface of the molding compound most adjacent to the first glass carrier substantially co-planar with a surface of the plurality of metal bonding pads most adjacent to the first glass carrier.

11: The method of forming a Fan-Out Wafer Level semiconductor device of claim 10 further comprising electrically and physically connecting the plurality of electrode pads formed on the active surface of the semiconductor chip with the plurality of metal bonding pads.

12: The method of forming a Fan-Out Wafer Level semiconductor device of claim 10 further comprising grinding the molding compound so that a surface of the molding compound least adjacent to the first glass carrier is substantially co-planar with a surface of the semiconductor chip.

13: The method of forming a Fan-Out Wafer Level semiconductor device of claim 10 further comprising filling an underfill into spaces between the semiconductor chip and the first glass carrier, and the molding compound encapsulating the semiconductor chip, the underfill, and the plurality of metal bonding pads.

14: The method of forming a Fan-Out Wafer Level semiconductor device of claim 13 wherein removing the first glass carrier is removing the first glass carrier to expose the plurality of metal bonding pads, the underfill, and a first surface of the molding compound and mounting a second glass carrier to a second surface of the molding compound, the semiconductor chip being between the first surface of the molding compound and the second surface of the molding compound.

15: The method of forming a Fan-Out Wafer Level semiconductor device of claim 14 further comprising forming the redistribution layer on the plurality of bonding pads, the underfill, and the first surface of the molding compound.

16: The method of forming a Fan-Out Wafer Level semiconductor device of claim 10 wherein a non-active surface of the semiconductor chip is adjacent to the first glass carrier and the method further comprises electrically connecting the plurality of electrode pads formed on the active surface of the semiconductor chip with the plurality of metal bonding pads using wire bonding, and the molding compound encapsulating the semiconductor chip, the wire bonding, and the plurality of metal bonding pads.

17: The method of forming a Fan-Out Wafer Level semiconductor device of claim 16 method further comprising electrically connecting at least one component, other than the semiconductor chip, with the plurality of metal bonding pads, and the molding compound encapsulates the semiconductor chip, the wire bonding, the at least one component, and the plurality of metal bonding pads.

18: The method of forming a Fan-Out Wafer Level semiconductor device of claim 10 further comprising forming another passivation layer between the first glass carrier and the metal bonding pads and forming the metal bonding pads on the another passivation layer and surrounded by the passivation layer.

19: The method of forming a Fan-Out Wafer Level semiconductor device of claim 18 further comprising forming a conductive layer to have a planar surface and planarly disposed on the another passivation layer and electrically connected to the plurality of metal bonding pads through conductive circuits formed to be coplanar to the plurality of metal bonding pads and through vias of the another passivation layer electrically coupled to the conductive circuits.

20: The method of forming a Fan-Out Wafer Level semiconductor device of claim 18 further comprising:
forming conductive circuits to be coplanar and electrically connected to the plurality of metal bonding pads; and
forming through vias of the another passivation layer electrically connected to the conductive circuits, the through vias being formed on only the periphery of the metal bonding pads.

21: The method of forming a Fan-Out Wafer Level semiconductor device of claim 9 further comprising mounting solder balls on the redistribution layer, at least one of the solder balls in electrical contact with the at least one metal trace.
